(19) United States
(12) Patent Application Publication
(10) Pub. No.: US 2025/0056818 A1
(43) Pub. Date: Feb. 13, 2025

(54) SEMICONDUCTOR DEVICE

(71) Applicant: UNITED MICROELECTRONICS CORP., Hsin-Chu City (TW)

(72) Inventors: Chang-Yih Chen, Tainan City (TW); Kuo-Hsing Lee, Hsinchu County (TW); Chun-Hsien Lin, Tainan City (TW)

(73) Assignee: UNITED MICROELECTRONICS CORP., Hsin-Chu City (TW)

(21) Appl. No.: 18/367,467

(22) Filed: Sep. 13, 2023

(30) Foreign Application Priority Data
Aug. 7, 2023 (TW) 112129489

(51) Int. Cl. H01L 29/94; H01L 27/06; H01L 29/66; H01L 29/78

(52) U.S. Cl. CPC H01L 29/94; H01L 27/0629; H01L 29/66181; H01L 29/66795; H01L 29/7851

(57) ABSTRACT

A semiconductor device includes a bottom portion, a middle portion, a top portion, and a base portion between the bottom portion and the substrate. Preferably, the bottom portion is surrounded by a shallow trench isolation (STI), a gate oxide layer is disposed on the fin-shaped structure and the STI, a bottom surface of the gate oxide layer is higher than a top surface of the base portion, a width of a top surface of the bottom portion is greater than half the width of the bottom surface of the bottom portion, and a tip of the top portion includes a tapered portion.

### BACKGROUND OF THE INVENTION

### 1. Field of the Invention

The invention relates to a semiconductor device, and more particularly, to a metal-oxide-semiconductor capacitor (MOSCAP) device.

### 2. Description of the Prior Art

Capacitor structure such as MOSCAP structures from semiconductor devices are typically incorporated from gate structure elements of metal-oxide semiconductor field effect transistors (MOSFETs). The fabrication of a typical MOSCAP structure could be accomplished by depositing a metal layer serving as a bottom electrode on a substrate, an insulating layer such as oxide layer on the bottom electrode, and a binary metal layer serving as top electrode on the oxide layer.

Typically, a thermal anneal process is conducted on the binary metal layer so that the metal layer could have adequate work function to be applied in MOSCAP devices. For instance, work function applied to MOSCAP in p-type and n-type MOS devices could be not less than 4.7 eV and not greater than 4.3 eV. However, the thermal anneal process conducted could induce transformations in layers other than the binary metal layer and results in chemical degeneration or physical embrittlement. Moreover, thermal treatment such as heating or thermal anneal processes conducted on other layers could also results in damages to binary metal layer having poor thermal instability. Accordingly, it becomes necessary to strictly control temperatures, duration, and atmospheres of thermal anneal process in fabricating MOSCAP structures, which not only increases difficulty but also cost of the process. Hence, how to come up with a novel MOSCAP device for resolving the above issues has become an important task in this field.

### SUMMARY OF THE INVENTION

According to an embodiment of the present invention, a semiconductor device includes a bottom portion, a middle portion, a top portion, and a base portion between the bottom portion and the substrate. Preferably, the bottom portion is surrounded by a shallow trench isolation (STI), a gate oxide layer is disposed on the fin-shaped structure and the STI, a bottom surface of the gate oxide layer is higher than a top surface of the base portion, a width of a top surface of the bottom portion is greater than half the width of the bottom surface of the bottom portion, and a tip of the top portion includes a tapered portion.

According to another aspect of the present invention, a semiconductor device includes a bottom portion, a middle portion, a top portion, and a base portion between the bottom portion and the substrate. Preferably, the bottom portion is surrounded by a shallow trench isolation (STI), a gate oxide layer is disposed on the fin-shaped structure and the STI, a bottom surface of the gate oxide layer is higher than a top surface of the base portion, a width of a top surface of the bottom portion is greater than half the width of the bottom surface of the bottom portion, and a tip of the top portion includes a round portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a semiconductor device according to an embodiment of the present invention.

FIG. 7 illustrates a structural view of a fin-shaped structure after being implanted with arsenic (As) through an ion implantation process.

FIG. 8 illustrates a structural view of a fin-shaped structure after being implanted with phosphorus (P) through an ion implantation process.

### DETAILED DESCRIPTION

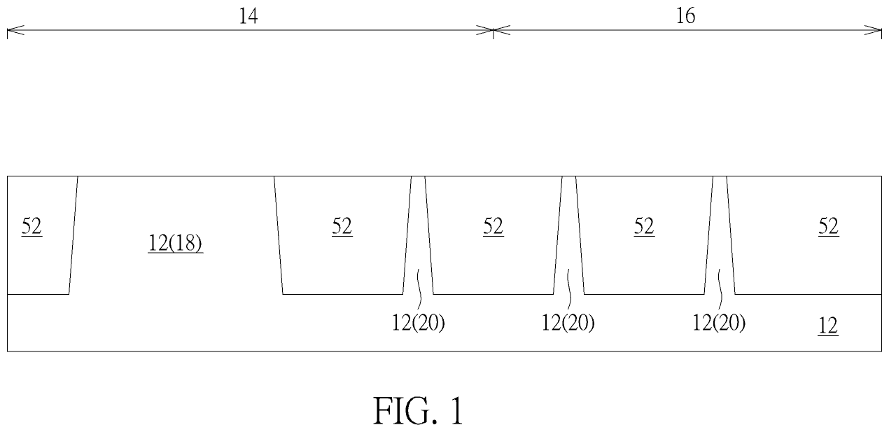

Referring to FIGS. 1-6, FIGS. 1-6 illustrate a method for fabricating a semiconductor device according to an embodiment of the present invention. As shown in FIG. 1, a substrate 12 such as a silicon substrate or silicon-on-insulator (SOI) substrate is provided and two or more regions including a non-MOSCAP region 14 and a MOSCAP region 16 are defined on the substrate 12, in which the non-MOSCAP region 14 could be used for fabricating input/output (I/O) devices of low-voltage (LV) devices while the MOSCAP region 16 could be used for fabricating a MOSCAP device in the later process.

Next, a base 18 and fin-shaped structure 20 are formed on the non-MOSCAP region 14 and a plurality of fin-shaped structures 20 are formed on the substrate 12 of the MOSCAP region 16. Preferably, the fin-shaped structures 20 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the base 18 and the fin-shaped structures 20 could also be obtained by first forming a patterned mask (not shown) on the substrate, 12, and through an etching process, the pattern of the patterned mask is transferred to the substrate 12 to form the base 18 and the fin-shaped structures 20. Moreover, the formation of the base 18 and the fin-shaped structures 20 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding the base 18 and fin-shaped structures 20. These approaches for forming the base 18 and fin-shaped structures 20 are all within the scope of the present invention.

Next, a flowable chemical vapor deposition (FCVD) process is conducted to form an insulating layer 52 made of silicon oxide on the base 18 and the fin-shaped structures 20 and filling the trenches between the base 18 and the fin-shaped structures 20, and a planarizing process such as chemical mechanical polishing (CMP) process is conducted to remove part of the insulating layer 52 so that the top surface of the remaining insulating layer 52 is even with the top surface of the fin-shaped structures 20.

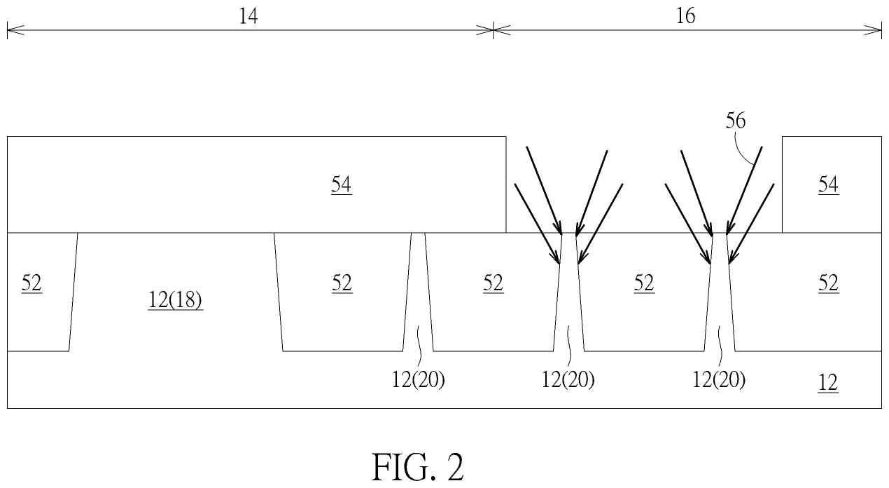

Next, as shown in FIG. 2, a patterned mask 54 such as patterned resist is formed on the non-MOSCAP region 14 and even part of the MOSCAP region 16 to expose part of the insulating layer 52 and fin-shaped structures 20 on the MOSCAP region 16, and then an ion implantation process 56 is conducted to implant dopants such as arsenic (As) and phosphorus (P) into the fin-shaped structures 20. It should be noted that the ion implantation process 56 conducted at this stage preferably pertains to be a tilted angle ion implantation process that implants the aforementioned ions into the fin-shaped structures 20 on the MOSCAP region 16 at a tilted angle. Preferably, the angle of implantation process 56 is between 0-25 degrees or most preferably at 15 degrees. Since the ion implantation process 56 conducted at this stage only implant ions into the fin-shaped structures 20 on the MOSCAP region 16 but not the ones one the non-MOSCAP region 14, the overall dopant concentration of the fin-shaped structures 20 on the MOSCAP region 16 is preferably greater than the overall dopant concentration of the fin-shaped structures 20 on the non-MOSCAP region 14 as the fin-shaped structures 20 doped with heavy ions on the MOSCAP region 16 could be used as a bottom electrode for the MOSCAP device in the later process.

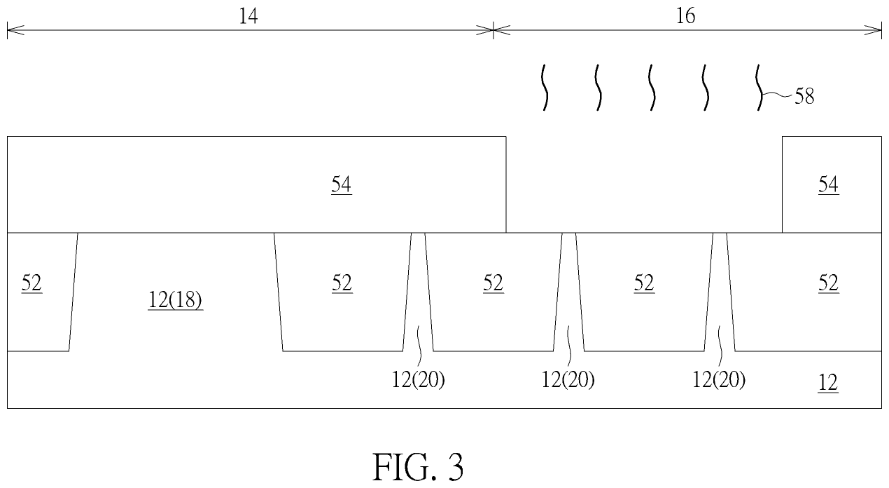

Next, as shown in FIG. 3, a thermal treatment process or more specifically a spike anneal process 58 is conducted by using high temperature to diffuse the aforementioned dopants into surrounding fin-shaped structures 20. Preferably, the temperature of the spike anneal process 58 is between 950-1250° C. and the duration of the spike anneal process 58 is between 0-3 seconds. The patterned mask 54 is then removed thereafter. It should be noted that even though this embodiment first conducts the spike anneal process 58 and then remove the patterned mask 54 thereafter, according to other embodiment of the present invention, it would also be desirable to strip the patterned mask 54 completely and then conduct the spike anneal process 58, which is also within the scope of the present invention.

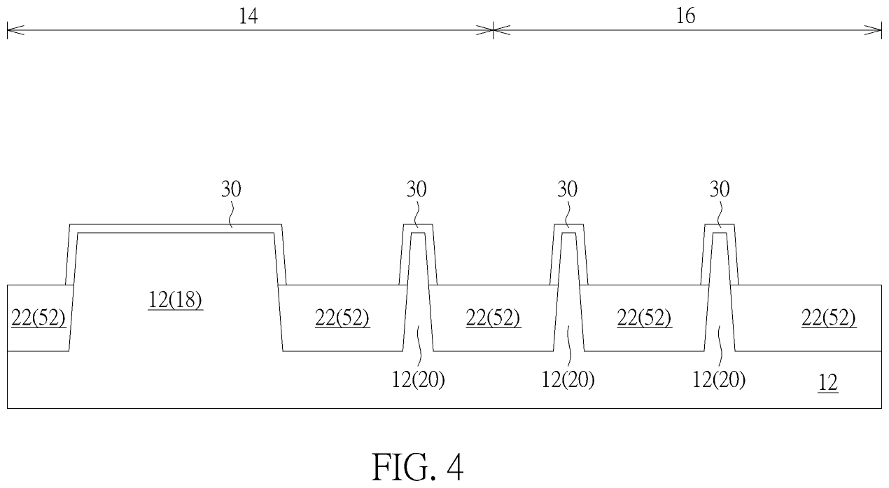

Next, as shown in FIG. 4, an etching process could be conducted to remove part of the insulating layer 52 on the non-MOSCAP region 14 and the MOSCAP region 16 so that the top surface of the remaining insulating layer 52 is slightly lower than the top surface of the fin-shaped structures 20 to form a shallow trench isolation (STI) 22. Next, an oxide growth process such as a rapid thermal oxidation (RTO) process or an in-situ steam generation (ISSG) is conducted to form a gate oxide layer 30 made of silicon oxide on the substrate 12 and fin-shaped structures 20 on the non-MOSCAP region 14 and MOSCAP region 16.

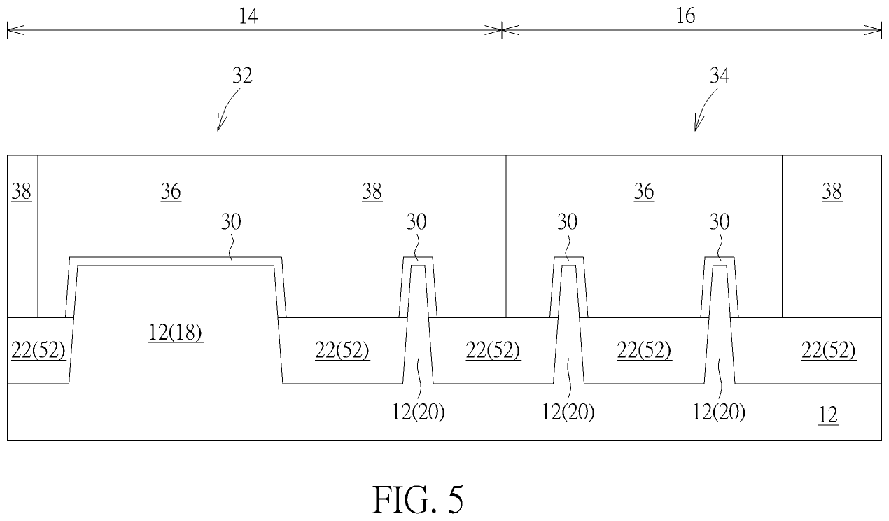

Next, as shown in FIG. 5, gate electrodes 32, 34 are formed on the substrate 12 and fin-shaped structures 20 on the non-MOSCAP region 14 and MOSCAP region 16 respectively, in which the gate electrode 32 formed on the non-MOSCAP region 14 could be served as gate electrode for I/O device or LV device, the gate electrode 34 formed on the MOSCAP region 16 could be used as top electrode for the MOSCAP device, and formation of the gate electrodes 32, 34 could be accomplished by a gate first process, a high-k first approach from gate last process, or a high-k last approach from gate last process.

Since this embodiment pertains to a high-k last approach, a gate material layer 36 made of polysilicon and a selective hard mask (not shown) could be formed sequentially on the substrate 12, and a photo-etching process is then conducted by using a patterned resist (not shown) as mask to remove part of the gate material layer 36 and part of the gate oxide layer 30 through single or multiple etching processes. After stripping the patterned resist, gate electrodes 32, 34 each made of a patterned material layer 36 is formed on the substrate 12 and fin-shaped structures 20 of the non-MOSCAP region 14 and MOSCAP region 16.

Next, at least a spacer (not shown) is formed on the sidewalls of the each of the gate electrodes 32, 34, a source/drain region (not shown) and/or epitaxial layer is formed in the fin-shaped structures 20 and/or substrate 12 adjacent to two sides of the spacer on the non-MOSCAP region 14, and selective silicide layers (not shown) could be formed on the surface of the source/drain region. In this embodiment, the spacer could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The source/drain region could include n-type dopants or p-type dopants depending on the type of device being fabricated.

Next, an interlayer dielectric (ILD) layer 38 is formed on the gate electrodes 32, 34 and a planarizing process such as CMP is conducted to remove part of the ILD layer 38 for exposing the gate material layers 36 or gate electrodes 32, 34 made of polysilicon so that the top surface of the gate electrodes 32, 34 are even with the top surface of the ILD layer 38.

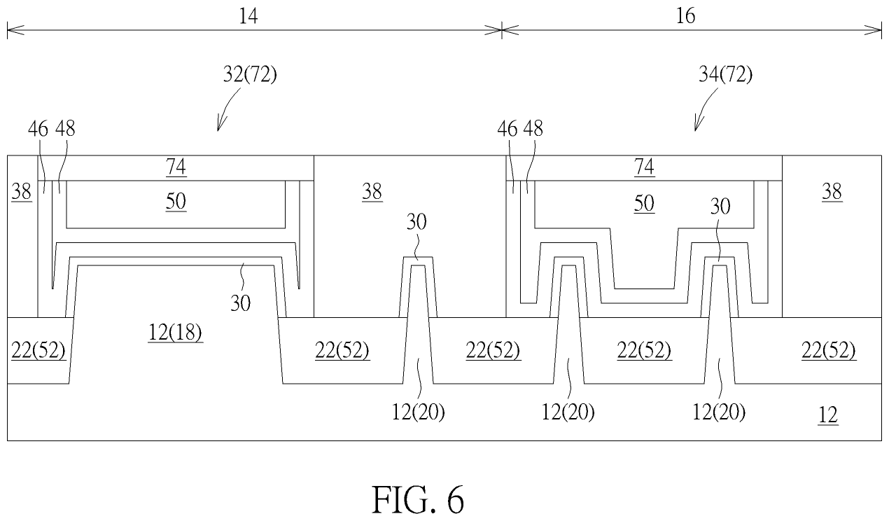

Next, as shown in FIG. 6, a replacement metal gate (RMG) process is conducted to transform the gate electrodes 32, 34 on the non-MOSCAP region 14 and MOSCAP region 16 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 36 and even gate oxide layer 30 for forming recesses (not shown) in the ILD layer 38.

Next, a selective interfacial layer (not shown) or gate dielectric layer, a high-k dielectric layer 46, a work function metal layer 48, and a low resistance metal layer 50 are formed in the recesses, and a planarizing process such as CMP is conducted to remove part of low resistance metal layer 50, part of work function metal layer 48, and part of high-k dielectric layer 46 to form metal gates 72. In this embodiment, the gate structures or metal gates 72 fabricated through high-k last process of a gate last process preferably includes an interfacial layer or gate oxide layer 30, a U-shaped high-k dielectric layer 46, a U-shaped work function metal layer 48, and a low resistance metal layer 50. Preferably, the fin-shaped structures 20 having heavy dopants serve as a bottom electrode for the MOSCAP device, dielectric layers including the gate oxide layer 30 and/or the high-k dielectric layer 46 serve as a capacitor dielectric layer for the MOSCAP device, and the gate electrode 34 including the work function metal layer 48 and low resistance metal layer 50 together serve as a top electrode for the MOSCAP device.

In this embodiment, the high-k dielectric layer 46 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 48 is formed for tuning the work function of the metal gate in accordance with the conductivity of the device. For an NMOS transistor, the work function metal layer 48 having a work function ranging between 3.9 V and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 48 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 48 and the low resistance metal layer 50, in which the material of the barrier layer may include titanium (Ti), titanium nitride (TiN), tantalum (Ta) or tantalum nitride (TaN). Furthermore, the material of the low-resistance metal layer 50 may include copper (Cu), aluminum (Al), titanium aluminum (TiAl), cobalt tungsten phosphide (CoWP) or any combination thereof.

Next, part of the high-k dielectric layer 46, part of the work function metal layer 48, and part of the low resistance metal layer 50 are removed to form recesses (not shown), and a hard mask 74 is formed into each of the recesses so that the top surfaces of the hard masks 74 and the ILD layer 38 are coplanar. Preferably the hard masks 74 could include SiO₂, SiN, SiON, SiCN, or combination thereof.

Next, a photo-etching process is conducted by using a patterned mask (not shown) as mask to remove part of the ILD layer 38 adjacent to the gate electrode 32 on the non-MOSCAP region 14 for forming contact holes (not shown) exposing the source/drain region underneath. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs electrically connecting the source/drain region. This completes the fabrication of a semiconductor device according to an embodiment of the present invention.

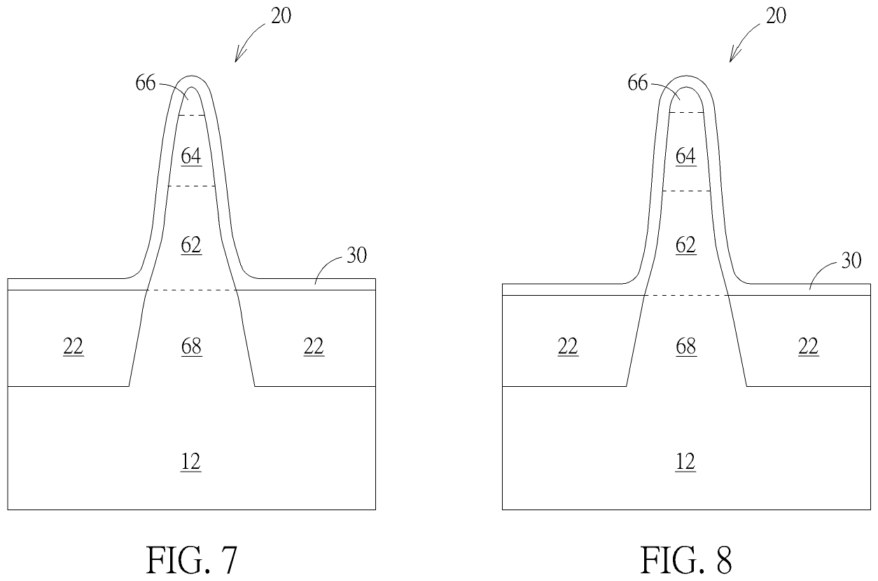

Referring to FIGS. 7-8, FIGS. 7-8 illustrate enlarged views of fin-shaped structures 20 after using ion implantation process to implant dopants into the fin-shaped structures 20 on the MOSCAP region 16 according to an embodiment of the present invention, in which FIG. 7 illustrates a structural view of a fin-shaped structure after being implanted with arsenic (As) through an ion implantation process and FIG. 8 illustrates a structural view of a fin-shaped structure after being implanted with phosphorus (P) through an ion implantation process. Preferably, elements including the gate electrodes 32, 34 on top of the gate oxide layer 30 are omitted in FIGS. 7-8. As shown in FIG. 7, the fin-shaped structure 20 containing As preferably includes a bottom portion 62, a middle portion 64, a top portion 66, and a base portion 68 between the bottom portion 62 and the substrate 12, in which the base portion 68 is surrounded by the STI 22, the gate oxide layer 30 is disposed on the fin-shaped structure 20 and the STI 22, the bottom surface of the gate oxide layer 30 could be even with or higher than the bottom surface of the base portion 68, the top surface or width of the top surface of the bottom portion 62 is greater than half the width of the bottom surface of the bottom portion 62, and the tip of the top portion 66 includes a tapered portion. In this embodiment, the tapered portion could be defined as the angle included by the tip or topmost point of the top portion 66 and two inclined sidewalls of the top portion 66 is between 0-30 degrees or most preferably less than 20 degrees.

Specifically, the bottom surface or width of the bottom surface of the bottom portion 62 is less than the height of the bottom portion 62, the bottom surface or width of the bottom surface of the middle portion 64 is equal to twice the width of the top surface of the middle portion 64, the height of the middle portion 64 is less than the height of the bottom portion 62, the bottom surface or bottom surface width of the top portion 66 is equal to the height of the top portion 66, and the height of the top portion 66 is less than the height of the middle portion 64.

According to an embodiment of the present invention, the bottom surface width of the bottom portion 62 is between 13-15 nm or most preferably 14 nm, the height of the bottom portion 62 is between 15-17 nm or most preferably 16 nm, the top surface width of the bottom portion 62 or bottom surface width of the middle portion 64 is between 7-9 nm or most preferably 8 nm, the height of the middle portion 64 is between 10-12 nm or most preferably 11 nm, the top surface width of the middle portion 64 or bottom surface width of the top portion 66 is between 3-5 nm or most preferably 4 nm, and the height of the top portion 66 is between 3-5 nm or most preferably 4 nm.

Next, as shown in FIG. 8, the fin-shaped structure 20 doped with phosphorus also includes a bottom portion 62, a middle portion 64, a top portion 66, and a base portion 68 between the bottom portion 62 and the substrate 12, in which the base portion 68 is surrounded by the STI 22, the gate oxide layer 30 is disposed on the fin-shaped structure 20 and the STI 22, the bottom surface of the gate oxide layer 30 could be even with or higher than the bottom surface of the base portion 68, and the top surface or width of the top surface of the bottom portion 62 is greater than half the width of the bottom surface of the bottom portion 62. In contrast to the tip of the fin-shaped structure 20 shown in FIG. 7 includes a tapered shape, the tip of the top portion 66 of the fin-shaped structure 20 in this embodiment includes a round portion. In this embodiment, the round portion could be defined as the top surface of the top portion 66 having substantially circular or orbicular surface while the angle included by the circular top surface and two inclined sidewalls of the top portion 66 is between 30-50 degrees or most preferably between 30-40 degrees.

Specifically, the bottom surface of bottom surface width of the bottom portion 62 is less than the height of the bottom portion 62, the bottom surface or bottom surface width of the middle portion 64 is less than half the height of the bottom portion 62, the height of the middle portion 64 is less than the height of the bottom portion 62, the bottom surface or bottom surface width of the top portion 66 is greater than the height of the top portion 66, and the height of the top portion 66 is less than the height of the middle portion 64.

According to an embodiment of the present invention, the bottom surface width of the bottom portion 62 is between 12-14 nm or most preferably 13 nm, the height of the bottom portion 62 is between 16-18 nm or most preferably 17 nm, the top surface width of the bottom portion 62 or bottom surface width of the middle portion 64 is between 6-8 nm or most preferably 7 nm, the height of the middle portion 64 is between 12-14 nm or most preferably 13 nm, the top surface width of the middle portion 64 or bottom surface width of the top portion 66 is between 4-6 nm or most preferably 5 nm, and the height of the top portion 66 is between 3-5 nm or most preferably 4 nm.

Overall, the present invention discloses an approach of using tilted angle ion implantation process for fabricating a MOSCAP device on a MOSCAP region, in which the fin-shaped structure of the MOSCAP device could be have different shape profiles depending on different types of dopants being implanted with adjustment of etching process conducted as part of the insulating layer 52 is removed to form the STI 22 as shown in FIG. 4. According to an embodiment of the present invention, as shown in FIG. 7, the fin-shaped structure being implanted with As preferably has substantially tapered portion on the tip portion while as shown in FIG. 8, the fin-shaped structure being implanted with P preferably has substantially round or circular profile on the tip portion. In addition to fabricating a MOSCAP device by using either of the two aforementioned fin-shaped structure profiles, the fin-shaped structure shown in FIG. 8 in particularly since having a slightly greater top surface area on the tip portion could be used more efficiently for increasing overall capacitance of the MOSCAP device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a fin-shaped structure on a substrate, wherein the fin-shaped structure comprises:
a bottom portion, wherein a top surface of the bottom portion is greater than half of a bottom surface of the bottom portion;
a middle portion; and
a top portion, wherein a tip of the top portion comprises a tapered portion.

2. The semiconductor device of claim 1, further comprising a base portion between the bottom portion and the substrate.

3. The semiconductor device of claim 2, further comprising a gate oxide layer on the fin-shaped structure, wherein a bottom surface of the gate oxide layer is higher than a top surface of the base portion.

4. The semiconductor device of claim 1, wherein a bottom surface of the bottom portion is less than a height of the bottom portion.

5. The semiconductor device of claim 1, wherein a bottom surface of the middle portion is equal to twice the width of the top surface of the middle portion.

6. The semiconductor device of claim 1, wherein a height of the middle portion is less than a height of the bottom portion.

7. The semiconductor device of claim 1, wherein a bottom surface of the top portion is equal to a height of the top portion.

8. The semiconductor device of claim 1, wherein a height of the top portion is less than a height of the middle portion.

9. The semiconductor device of claim 1, wherein a surface of the fin-shaped structure comprises arsenic (As).

10. A semiconductor device, comprising:
a fin-shaped structure on a substrate, wherein the fin-shaped structure comprises:
a bottom portion, wherein a top surface of the bottom portion is greater than half of a bottom surface of the bottom portion;
a middle portion; and
a top portion, wherein a tip of the top portion comprises a round portion.

11. The semiconductor device of claim 10, further comprising a base portion between the bottom portion and the substrate.

12. The semiconductor device of claim 11, further comprising a gate oxide layer on the fin-shaped structure, wherein a bottom surface of the gate oxide layer is higher than a top surface of the base portion.

13. The semiconductor device of claim 10, wherein a bottom surface of the bottom portion is less than a height of the bottom portion.

14. The semiconductor device of claim 10, wherein a bottom surface of the middle portion is less than half a height of the bottom portion.

15. The semiconductor device of claim 10, wherein a height of the middle portion is less than a height of the bottom portion.

16. The semiconductor device of claim 10, wherein a bottom surface of the top portion is great than a height of the top portion.

17. The semiconductor device of claim 10, wherein a height of the top portion is less than a height of the middle portion.

18. The semiconductor device of claim 10, wherein a surface of the fin-shaped structure comprises phosphorus (P).
